(19) United States
(12) Patent Application Publication
(10) Pub. No.: US 2026/0173660 A1
(43) Pub. Date: Jun. 18, 2026

(54) DISPLAY PANEL AND DISPLAY APPARATUS

(71) Applicants: Hefei Visionox Technology Co., Ltd., Hefei (CN); Visionox Technology Inc., Kunshan (CN)

(72) Inventors: Zhiwei ZHOU, Hefei (CN); Yingyu FENG, Kunshan (CN); Jinfang ZHANG, Hefei (CN); Lu ZHANG, Kunshan (CN); Zhonghou WU, Hefei (CN)

(73) Assignees: Hefei Visionox Technology Co., Ltd., Hefei (CN); Visionox Technology Inc., Kunshan (CN)

(21) Appl. No.: 19/396,203

(22) Filed: Nov. 20, 2025

(30) Foreign Application Priority Data
Dec. 13, 2024 (CN) 202411847126.2

(51) Int. Cl. H10K 59/122; H10K 59/131; H10K 59/80; H10K 102/00

(52) U.S. Cl. CPC H10K 59/122; H10K 59/131; H10K 59/873; H10K 2102/351

(57) ABSTRACT

Embodiments of the present application provide a display panel and a display apparatus. The display panel has an active area and a non-active area. The display panel includes: a substrate; an isolation structure provided on one side of the substrate and including an isolation portion and a lap portion, where the isolation portion encloses to form a plurality of isolation openings located in the active area, and the lap portion is located in the non-active area; and a plurality of light-emitting devices, at least part of each light-emitting device being located in each corresponding isolation opening, where a width of the isolation portion between two adjacent light-emitting devices is a first width, and along a first arrangement direction of the isolation portion and the lap portion, a minimum width of the lap portion is a second width, the second width being greater than the first width.

### CROSS-REFERENCE TO RELATED APPLICATIONS

The present application claims priority to Chinese Patent Application No. 202411847126.2, titled “DISPLAY PANEL AND DISPLAY APPARATUS” and filed on Dec. 13, 2024, which is hereby incorporated by reference in its entirety.

### FIELD

The present application relates to the field of display devices, and particularly to a display panel and a display apparatus.

### BACKGROUND

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Reference can be made to relevant contents of the fine metal mask-free technology recited in Chinese patents CN 118251982 A, CN 116648095 A, CN 117062489 A, CN 118742138 A, CN 118678783 A, CN 118660598 A, CN 118675450 A, CN 118824188 A, and CN 118781966 A.

### SUMMARY

Embodiments of the present application provide a display panel and a display apparatus, with the aim of improving the process performance of the display panel.

An embodiment of the present application provides a display panel having an active area and a non-active area. The display panel includes: a substrate; an isolation structure provided on one side of the substrate and including an isolation portion and a lap portion, where the isolation portion encloses to form a plurality of isolation openings located in the active area, and the lap portion is located in the non-active area; and a plurality of light-emitting devices, at least part of each light-emitting device being located in each corresponding isolation opening, where a width of the isolation portion between two adjacent light-emitting devices is a first width, and along a first arrangement direction of the isolation portion and the lap portion, a minimum width of the lap portion is a second width, the second width being greater than the first width.

An embodiment of the present application further provides a display apparatus, including the display panel in any one of the foregoing embodiments.

### BRIEF DESCRIPTION OF THE DRAWINGS

By reading the following detailed description of non-limiting embodiments made with reference to the drawings, the other features, objectives and advantages of the present application will become more apparent, in which the same or similar features are denoted by the same or similar reference signs.

FIG. 1 is a schematic structure diagram of a display panel according to an embodiment of the present application;

FIG. 2 is a schematic partial enlarged structure diagram at C in FIG. 1 according to one example;

FIG. 3 is a cross-sectional view taken along E-E in FIG. 2 according to one example;

FIG. 4 is a cross-sectional view taken along F-F in FIG. 2 according to one example;

FIG. 5 is a cross-sectional view taken along F-F in FIG. 2 according to another example;

FIG. 6 is a schematic partial enlarged structure diagram at C in FIG. 1 according to another example;

FIG. 7 is a schematic structure diagram of another display panel according to an embodiment of the present application;

FIG. 8 is a schematic partial enlarged structure diagram at D in FIG. 7 according to one example;

FIG. 9 is a schematic structure diagram of yet another display panel according to an embodiment of the present application; and

FIG. 10 is a schematic structure diagram of still another display panel according to an embodiment of the present application.

### LIST OF REFERENCE SIGNS

100: substrate; 110: driving unit; 120: pixel defining layer; 130: conductive connection layer; 140: insulation layer;
210: isolation structure; 211: isolation portion; 2111: first isolation portion; 2112: second isolation portion; 2113: third isolation portion; 212: lap portion; 201: first sub-layer; 202: second sub-layer; 220: isolation opening;
300: light-emitting device; 311: first electrode; 312: light-emitting structure; 313: second electrode; 301: first light-emitting structure; 302: second light-emitting structure; 303: third light-emitting structure;
410: first encapsulation layer; 420: second encapsulation layer; 430: third encapsulation layer;
K1: first opening; K11: first sub-opening; K12: second sub-opening; K2: second opening;
K3: third opening; K4: fourth opening; G1: first via; G2: second via; L: signal line;
X: second arrangement direction; Y: first arrangement direction; Z: thickness direction;
AA: active area; NA: non-active area; DA: lap area; GA: transition area; GA1: first transition area; GA2: second transition area; GA3: third transition area.

### DETAILED DESCRIPTION OF THE EMBODIMENTS

The features and exemplary embodiments of the present application in various embodiments are described in detail below. In the following detailed description, many specific details are set forth to comprehensively understand the present application. However, it will be very apparent that the present application may be implemented without some of these specific details. The following description of the embodiments are merely to provide a better understanding for the present application by illustrating examples of the present application. In the drawings and the following description, at least part of known structures and techniques are not shown to avoid unnecessary ambiguousness of the present application; and for the ease of clarity, the dimensions of part of the structure may be enlarged. In addition, the features, structures, or characteristics described below may be combined, in any suitable manner, in one or more embodiments.

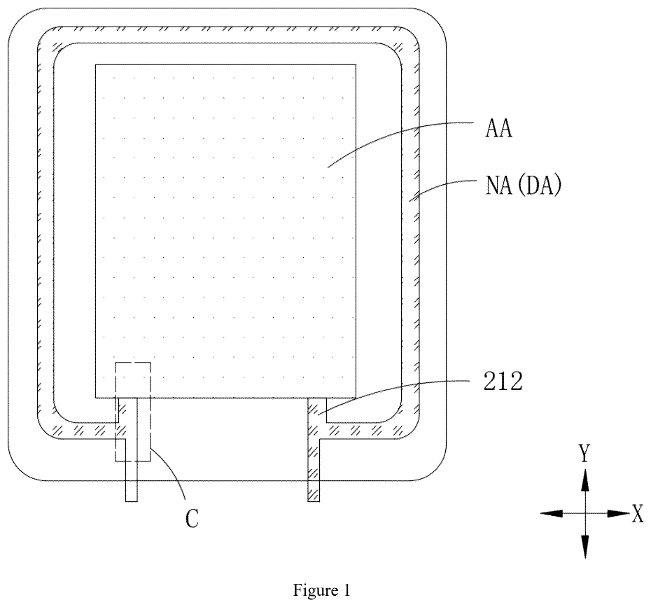

In order to better understand the present application, a display panel and a display apparatus according to embodiments of the present application will be described in detail below with reference to FIGS. 1 to 10.

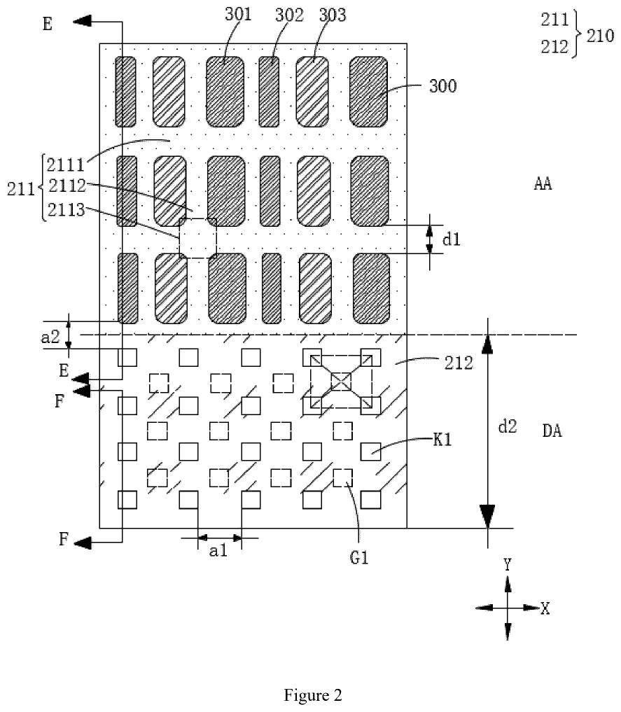

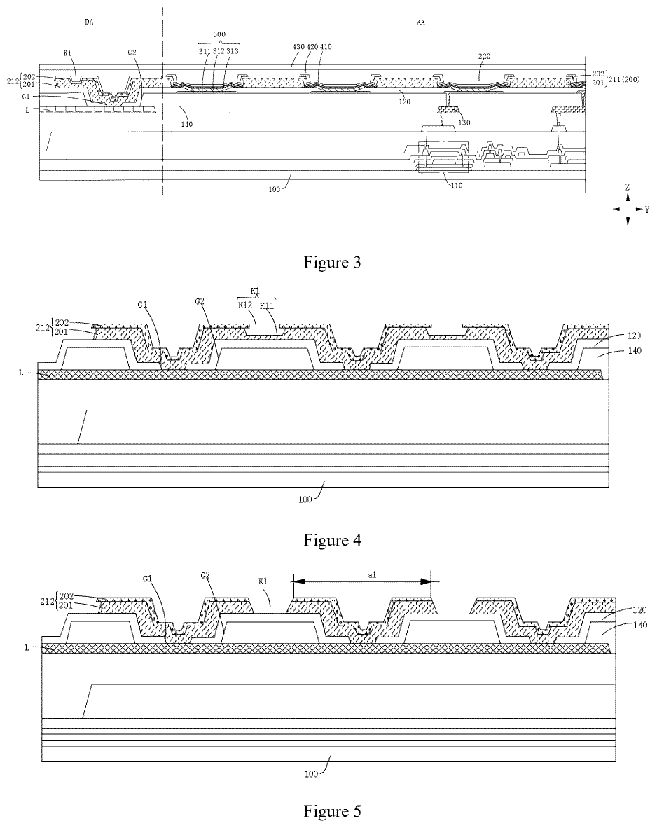

Referring to FIGS. 1 and 3 together, FIG. 1 is a schematic structure diagram of a display panel according to an embodiment of the present application; FIG. 2 is a schematic partial enlarged structure diagram at C in FIG. 1 according to one example; and FIG. 3 is a cross-sectional view taken along E-E in FIG. 2 according to one example.

As shown in FIGS. 1 to 3, an embodiment of the present application provides a display panel having an active area AA and a non-active area NA. The display panel includes: a substrate 100; an isolation structure 210 provided on one side of the substrate 100 and including an isolation portion 211 and a lap portion 212, where the isolation portion 211 encloses to form a plurality of isolation openings 220 located in the active area AA, and the lap portion 212 is located in the non-active area NA; and a plurality of light-emitting devices 300, at least part of each light-emitting device 300 being located in each corresponding isolation opening 220, where a width of the isolation portion 211 between two adjacent light-emitting devices 300 is a first width d1, and along a first arrangement direction Y of the isolation portion 211 and the lap portion 212, a minimum width of the lap portion 212 is a second width d2, the second width d2 being greater than the first width d1.

The display panel provided by the embodiment of the present disclosure includes the substrate 100, the isolation structure 210, and the light-emitting devices 300. At least part of each light-emitting device 300 is located in each corresponding isolation opening 220 to enable light emission and display of the display panel. The isolation structure 210 can serve to isolate adjacent light-emitting devices 300, thereby improving light mixing effects between different light-emitting devices 300. The isolation structure 210 extends from the active area AA to the non-active area NA. The isolation structure 210 in the active area AA, namely, the isolation portion 211, encloses to form the isolation openings 220 to accommodate the light-emitting devices 300. The lap portion 212 located in the non-active area NA is configured to direct signals to the light-emitting devices 300. The width of the isolation portion 211 between the two adjacent light-emitting devices 300 is the first width d1. Along the first arrangement direction Y of the isolation portion 211 and the lap portion 212, the minimum width of the lap portion 212 is the second width d2. The first arrangement direction Y may be a direction from the isolation portion 211 toward the lap portion 212 or from the lap portion 212 toward the isolation portion 211. A larger width of the isolation portion 211 or the lap portion 212 results in a corresponding lower impedance and lower current density. Therefore, by constraining the second width d2 to be greater than the first width d1, the present application allows for an increase in the width of the lap portion 212 along the first arrangement direction Y to reduce a signal voltage drop at the lap portion 212 and decrease a current density in the lap portion 212, which mitigates the problem of thermal burn in the non-active area NA of the display panel caused by a high current density. This enhances the reliability and process performance of the display panel.

In one embodiment, the isolation portion 211 and the lap portion 212 are sub-components of the isolation structure 210 in different areas (e.g., the active area AA and the non-active area NA) of the display panel. The isolation portion 211 and the lap portion 212 are of an integral structure; that is, there is no discontinuity between the isolation portion 211 located in the active area AA and the lap portion 212 located in the non-active area NA. The isolation portion 211 and the lap portion 212 are an integral structure, and the material of the isolation portion 211 and the lap portion 212 extends continuously across the active area AA and the non-active area NA. The isolation portion 211 and the lap portion 212 are formed in the same process step, which can simplify the process of preparing the display panel.

In one embodiment, the substrate 100 may be a rigid substrate, such as a glass substrate; or may be a flexible substrate, which may be made of polyimide, polystyrene, polyethylene terephthalate, poly-p-xylylene, polyethersulfone or polyethylene naphthalate. The substrate 100 is mainly configured to support a device arranged thereon.

In some embodiments, the isolation structure 210 includes a conductive material, and the light-emitting devices 300 include a first electrode 311, a light-emitting structure 312, and a second electrode 313 sequentially stacked in a direction away from the substrate 100, where the second electrode 313 is electrically connected to the isolation portion 211. The direction away from the substrate 100 may be parallel to a thickness direction Z of the display panel.

The material of the first electrode 311 is typically a material having a high work function, to enhance hole injection efficiency, and may be gold (Au), platinum (Pt), titanium (Ti), silver (Ag), indium tin oxide (ITO), zinc tin oxide (IZO), transparent conductive polymers (e.g., polyaniline), or the like. For example, the first electrode 311 may be made of an ITO-Ag-ITO composite material, without any specific limitations.

The material of the second electrode 313 may be one of metal materials such as silver (Ag), aluminum (Al), lithium (Li), magnesium (Mg), ytterbium (Yb), calcium (Ca), or indium (In), or may be an alloy of the foregoing metal materials, such as a magnesium-silver alloy (Mg/Ag), and a lithium-aluminum alloy (Li/Al), which is not limited in this embodiment.

In one embodiment, the light-emitting structure 312 includes one or more of an electron injection layer, an electron transport layer, a light-emitting material layer, a hole blocking layer, an electron blocking layer, a hole transport layer, and a hole injection layer. The specific layer(s) may be selected according to the specific type of the light-emitting layer, without any specific limitations. The electron injection layer, the electron transport layer, and the hole blocking layer may be provided between the second electrode 313 and the light-emitting material layer. The electron blocking layer, the hole transport layer, and the hole injection layer may be provided between the first electrode 311 and the light-emitting material layer.

Referring to FIGS. 2 to 5, in some embodiments, the lap portion 212 includes a plurality of first openings K1, each first openings K1 extending from one side of the lap portion 212 facing away from the substrate 100 toward the substrate 100, where two adjacent first openings K1 have a first distance a1 defined therebetween, the first distance a1 being greater than the first width d1.

It should be noted that the first opening K1 extending from one side of the lap portion 212 facing away from the substrate 100 toward the substrate 100 means that the first opening K1 may completely penetrate through the lap portion 212, or may not penetrate through the lap portion 212; that is, the first opening K1 may be configured as a blind hole. When the first openings K1 are provided, the first distance a1 between adjacent first openings K1 is the width of the lap portion 212 between the adjacent first openings K1, and this width affects the current density in the lap portion 212 between the adjacent first openings K1. Therefore, in this embodiment, the first distance a1 is set to be greater than the first width d1 to decrease the impedance of the lap portion 212 between the adjacent first openings K1 and decrease the current density in the lap portion 212, thereby mitigating the problem of thermal burn caused by a high current density.

Providing the first openings K1 can increase the adhesion between a deposited film layer, e.g., an inorganic encapsulation layer, on the lap portion 212 and the lap portion 212, thereby mitigating the problem of film layer peeling. In addition, this can increase the light transmittance of the isolation structure 210 and thus the light transmittance of the display panel. Furthermore, by providing the first openings K1 in the lap portion 212 and providing the isolation openings 220 in the isolation portion 211, the distribution density of the conductive material on the lap portion 212 and the distribution density of the conductive material on the isolation portion 211 are made comparable, resulting in similar reflectivity between the lap portion 212 and the isolation portion 211, thereby mitigating the problem of display variations between the active area AA and the non-active area NA. The first openings K1 may further facilitate gas permeation, thereby increasing the yield of the display panel.

In one embodiment, the first distance a1 is not less than 1.5 times the first width d1; that is, the width of the lap portion 212 between the two adjacent first openings K1 is greater than or equal to 1.5 times the first width d1. This ensures that the impedance of the lap portion 212 remains sufficiently low to prevent the problem of thermal burn.

In one embodiment, the first width d1 is not less than 3 μm and not greater than 20 μm. For example, the first width d1 may be equal to any one of 3 μm, 5 μm, 10 μm, 15 μm, or 20 μm.

In one embodiment, the second width d2 is not less than 50 μm and not greater than 1000 μm. For example, the second width d2 may be equal to any one of 50 μm, 200 μm, 400 μm, 600 μm, 800 μm, or 1000 μm.

In one embodiment, the first distance a1 is not less than 10 μm and not greater than 70 μm. For example, the first distance a1, namely, the width of the lap portion 212 between the two adjacent first openings K1, may be equal to any one of 10 μm, 20 μm, 30 μm, 40 μm, 50 μm, 60 μm, or 70 μm.

In one embodiment, along a first direction, a width of the isolation portion 211 between two adjacent light-emitting devices 300 is the first width d1; or along a second direction, a width of the isolation portion 211 between two adjacent light-emitting devices 300 is the first width d1, where the first direction and the second direction are both parallel to the substrate 100, and the first direction intersects with the second direction, for example, along the first direction and the second direction, a maximum width of the isolation portion 211 between two adjacent light-emitting devices 300 is the first width d1.

In one embodiment, along the first direction, a minimum width of the lap portion 212 is the second width d2; or along the second direction, a minimum width of the lap portion 212 is the second width d2, where the first direction and the second direction are both parallel to the substrate 100, and the first direction intersects with the second direction.

It can be understood that when the width of the lap portion 212 along the first direction is less than the width of the lap portion 212 along the second direction, the second width d2 may be the width of the lap portion 212 along the first direction; or when the width of the lap portion 212 along the first direction is greater than the width of the lap portion 212 along the second direction, the second width d2 may be the width of the lap portion 212 along the second direction.

In one embodiment, the distance between the two adjacent first openings K1 may be specifically the distance along the direction of the connecting line between the centers of the two first openings K1. That is, when the first openings K are arranged along the first direction, the two adjacent first openings K1 have the first distance a1 defined therebetween along the first direction; and/or when the first openings K1 are arranged along the second direction, the two adjacent first openings K1 have the first distance a1 defined therebetween along the second direction, where the first direction and the second direction are both parallel to the substrate 100, and the first direction intersects with the second direction.

In one embodiment, an area of a shape enclosed by an orthographic projection of the contour of the first opening K1 on the substrate 100 is less than an area of an orthographic projection of the isolation opening 220 on the substrate 100; that is, the size of the isolation opening 220 is greater than the size of the first opening K1.

Referring to FIG. 5, in some embodiments, the first opening K1 penetrates through the lap portion 212; that is, the first opening K1 may be a through hole, and portions of the lap portion 212 are separated by the first opening K1. When the first opening K1 penetrates through the lap portion 212, the heat dissipation effect is better.

Referring to FIG. 4, in some embodiments, a distance the first opening K1 extends from the side of the lap portion 212 facing away from the substrate 100 toward the substrate 100 is less than a thickness of the lap portion 212 in a direction perpendicular to the substrate 100. That is, the first opening K1 does not penetrate through the lap portion 212, but only with the material of the lap portion 212 on one side surface of the lap portion 212 facing away from the substrate 100 being partially removed to form the first opening K1. This ensures that the lap portion 212 is not completely disconnected, which equivalently increases the width of the lap portion 212 and thus mitigates burn.

Referring to FIGS. 4 and 5, in some embodiments, the isolation structure 210 includes a first sub-layer 201 and a second sub-layer 202 sequentially stacked along a direction away from the substrate 100, where an orthographic projection of the first sub-layer 201 on the substrate 100 is within an orthographic projection of the second sub-layer 202 on the substrate 100.

Referring to FIG. 5, the first opening K1 penetrates through the second sub-layer 202 and the first sub-layer 201.

It can be understood that the first opening K1 may penetrate through the first sub-layer 201 and the second sub-layer 202 to expose a film layer below the lap portion 212, where the film layer below may be specifically an insulation layer 140. The orthographic projection of the first sub-layer 201 on the substrate 100 being within the orthographic projection of the second sub-layer 202 on the substrate 100 means that the size of the first sub-layer 201 is less than or equal to the size of the second sub-layer 202.

In one embodiment, the first sub-layer 201 includes an aluminum metal material, and the second sub-layer 202 includes a titanium metal material.

In one embodiment, the lap portion 212 further includes a fifth sub-layer located on one side of the first sub-layer 201 facing the substrate 100, where the orthographic projection of the first sub-layer 201 on the substrate 100 is within an orthographic projection of the fifth sub-layer on the substrate 100. The first opening K1 may also penetrate through the fifth sub-layer.

Referring to FIG. 4, in some embodiments, the first opening K1 penetrates through the second sub-layer 202 and extends into the first sub-layer 201, where a distance the first opening K1 extends into the first sub-layer 201 is less than a thickness of the first sub-layer 201 in the direction perpendicular to the substrate 100.

In this embodiment, the first opening K1 penetrates through the second sub-layer 202 but does not penetrate through the first sub-layer 201, which can be achieved by a half-etching process. This ensures that the first sub-layer 201 remains connected and is not interrupted by the first opening K1. This configuration equivalently increases the trace width of the lap portion 212 and thus mitigates burn.

In one embodiment, the first opening K1 includes a first sub-opening K11 and a second sub-opening K12 that are in communication, where the first sub-opening K11 is provided in the first sub-layer 201, and the second sub-opening K12 is provided in the second sub-layer 202. A shape enclosed by an orthographic projection of the contours of the second sub-opening K12 on the substrate 100 is within a shape enclosed by an orthographic projection of the contours of the first sub-opening K11 on the substrate 100; that is, the size of the second sub-opening K12 is less than or equal to the size of the first sub-opening K11. When the size of the second sub-opening K12 is less than the size of the first sub-opening K11, the second sub-layer 202 protrudes toward the center of the second sub-opening K12 relative to the first sub-layer 201. A deposited film layer, such as an inorganic encapsulation layer, on the lap portion 212 may partially recess into the first sub-opening K11 and the second sub-opening K12 to increase the adhesion between the inorganic encapsulation layer and the lap portion 212, thereby preventing film layer peeling.

Referring to FIG. 2, in some embodiments, the plurality of isolation openings 220 and the plurality of first openings K1 have a second distance a2 defined therebetween, the second distance a2 being greater than the first width d1. In one embodiment, along the first arrangement direction Y, the plurality of isolation openings 220 and the plurality of first openings K1 have the second distance a2 defined therebetween.

Considering that the isolation portion 211 and the lap portion 212 are connected, the width of the lap portion 212 between the isolation opening 220 and the first opening K1 should not be too small, as a too small width would cause an excessive current density in this portion of the lap portion 212. Therefore, in this embodiment, the plurality of isolation openings 220 and the plurality of first openings K1 are configured to have the second distance a2 defined therebetween, and the second distance a2 is greater than the first width d1. The second distance a2 is one of the corresponding plurality of distances between the plurality of isolation openings 220 and the plurality of first openings K1. This ensures that even the lap portion 212 having the minimum width between the isolation opening 220 and the first opening K1 will not experience overheating due to an excessive current density.

In one embodiment, the second distance a2 is not less than 8 μm and not greater than 50 μm. For example, the second distance a2 may be equal to any one of 8 μm, 20 μm, 30 μm, 40 μm, or 50 μm.

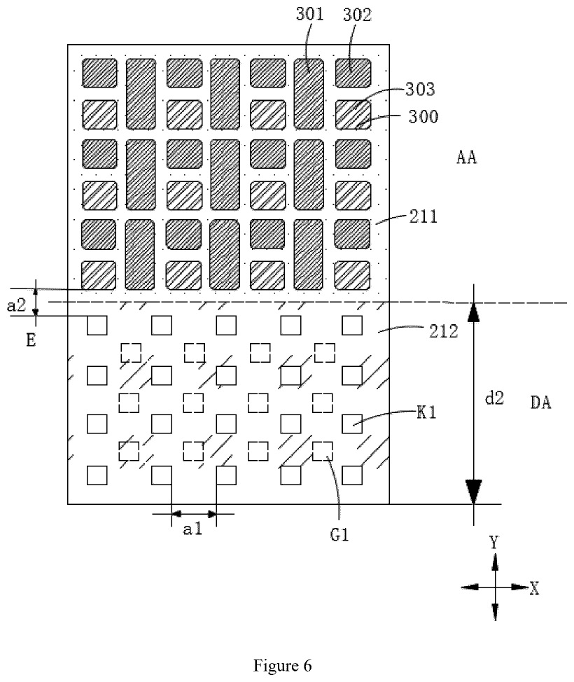

Referring to FIG. 2 or 6, in some embodiments, the isolation portion 211 includes a first isolation portion 2111 extending in a first direction parallel to the substrate 100, a second isolation portion 2112 extending in a second direction parallel to the substrate 100, and a third isolation portion 2113 connected to both the first isolation portion 2111 and the second isolation portion 2112, where the first direction intersects with the second direction. A maximum width of at least one third isolation portion 2113 is greater than a maximum width of the first isolation portion 2111 connected to the third isolation portion, and a maximum width of at least one third isolation portion 2113 is greater than a maximum width of the second isolation portion 2112 connected to the third isolation portion.

It can be understood that the maximum width of the third isolation portion 2113 is greater than both the maximum widths of the first isolation portion 2111 and the second isolation portion 2112 that are connected to the third isolation portion. Therefore, the first width d1 of the isolation portion 211 may be the maximum width of the third isolation portion 2113.

Depending on the specific configuration of the third isolation portion 2113, the maximum width of the third isolation portion 2113 may be the width of the third isolation portion 2113 in the first direction, the width of the third isolation portion 2113 in the second direction, or the width of the third isolation portion 2113 in another direction. For example, the third isolation portion 2113 may have the maximum width in a direction that forms a 45° angle with both the first direction and the second direction. The specific configuration depends on the actual arrangement patterns and dimensions of the first isolation portion 2111, the second isolation portion 2112, and the third isolation portion 2113, and is not limited to the examples described above.

Due to factors such as manufacturing process, the light-emitting structure 312 has curved chamfers, and the maximum width of the third isolation portion 2113 corresponding to the curved chamfers is thus greater than the maximum widths of the first isolation portion 2111 and the second isolation portion 2112.

As shown in FIG. 2, the light-emitting structures 312 are arranged in an array along the first arrangement direction Y and a second arrangement direction X. In one embodiment, the light-emitting structures 312 include a first light-emitting structure 301, a second light-emitting structure 302, and a third light-emitting structure 303 that emit different colors of light. The first light-emitting structure 301, the second light-emitting structure 302, and the third light-emitting structure 303 are sequentially arranged along the second arrangement direction X and repeatedly arranged along the first arrangement direction Y. In this embodiment, the third isolation portion 2113 has the maximum width in the direction that forms a 45° angle with both the first direction and the second direction.

In some embodiments, as shown in FIG. 6, the second light-emitting structure 302 and the third light-emitting structure 303 are adjacently arranged along the first arrangement direction Y, and the second light-emitting structure 302 and the third light-emitting structure 303 are arranged adjacently to the first light-emitting structure 301 along the second arrangement direction X.

In one embodiment, the first direction and the second direction are perpendicular to each other.

In one embodiment, the first direction is parallel to the first arrangement direction Y. The second direction is parallel to the second arrangement direction X.

Referring to FIG. 3, in some embodiments, the display panel further includes: a pixel defining layer 120 provided on one side of the substrate 100 and located in the active area AA and the non-active area NA, where the pixel defining layer 120 encloses to form a plurality of pixel openings in the active area AA, and each pixel opening is in communication with each corresponding isolation opening 220. Orthographic projections of the plurality of first openings K1 on the substrate 100 are within an orthographic projection of the pixel defining layer 120 on the substrate 100.

In this embodiment, the light-emitting device 300 may be disposed in the pixel opening to enable light emission and display of the display panel.

In one embodiment, the plurality of pixel openings are spaced apart, and each pixel opening has the light-emitting device 300 disposed therein.

The orthographic projections of the plurality of first openings K1 on the substrate 100 are within the orthographic projection of the pixel defining layer 120 on the substrate 100; that is, the isolation structure 210 may be disposed corresponding to the pixel defining layer 120. In one embodiment, the isolation structure 210 is located on one side of the pixel defining layer 120 facing away from the substrate 100. When the first opening K1 penetrates through the lap portion 212, the first opening K1 may expose the pixel defining layer 120.

Referring to FIGS. 3 to 5, optionally, the pixel defining layer 120 further includes at least one first via G1 located in the non-active area NA. The display panel further includes: a driving layer, provided between the substrate 100 and the pixel defining layer 120 and located in the active area AA and the non-active area NA, including at least one power signal line L located in the non-active area NA, where part of a surface on a side of the at least one power signal line L facing away from the substrate 100 is exposed from the at least one first via G1. The lap portion 212 is electrically connected to the at least one power signal line L through the at least one first via G1.

In one embodiment, the driving layer includes a driving unit 110, where the driving unit 110 may include a thin-film transistor. In the active area AA, the driving unit 110 and the light-emitting device 300 are electrically connected through a conductive connection layer 130, and the power signal line L may be provided in the same layer as the conductive connection layer 130.

In this embodiment, part of a surface of the at least one power signal line L facing away from the substrate 100 is exposed from the at least one first via G1; that is, the power signal line L may extend into the first via G1 and be electrically connected to the lap portion 212 through the first via G1. A plurality of first vias G1 and a plurality of power signal lines L corresponding to the plurality of first vias G1 may be simultaneously provided according to actual needs, to simultaneously supply power signals to the lap portion 212.

In one embodiment, the power signal line L may be specifically an ELVSS (low-level power signal line L) for supplying a low-level power signal to the light-emitting structure 312.

In one embodiment, the driving layer further includes an insulation layer 140 provided between the at least one power signal line L and the pixel defining layer 120, where the insulation layer 140 includes at least one second via G2, and an orthographic projection of the at least one first via G1 on the substrate 100 is within an orthographic projection of the at least one second via G2 on the substrate 100.

It can be understood that, the orthographic projection of the at least one first via G1 on the substrate 100 being within the orthographic projection of the at least one second via G2 on the substrate 100 means that the size of the second via G2 is greater than or equal to the size of the first via G1, to facilitate electrical connection of the power signal line L to the lap portion 212 sequentially through the second via G2 and the first via G1.

In one embodiment, the at least one first via G1 includes a plurality of first vias G1, the at least one second via G2 includes a plurality of second vias G2, and the plurality of first vias G1 and the plurality of second vias G2 are arranged in a one-to-one correspondence. That is, there are both a plurality of first vias G1 and a plurality of second vias G2, and the first vias G1 and the second vias G2 are provided in a one-to-one correspondence, to ensure the electrical connection effect between the power signal lines L and the lap portion 212.

In one embodiment, the insulation layer 140 includes an organic material to improve flatness of the film layer. For example, the material of the insulation layer 140 may include hexamethyldisiloxane, epoxy resin, or polyimide, or may include another material, which is not limited in this embodiment.

In one embodiment, the pixel defining layer 120 includes an inorganic material to ensure insulation performance.

In one embodiment, the pixel defining layer 120 covers a side surface of the insulation layer 140 facing the at least one second via G2; that is, the pixel defining layer 120 partially extends into the second via G2.

Referring to FIG. 2, in some embodiments, the plurality of first openings K1 are arranged in an array in the first direction and the second direction, where the first direction intersects with the second direction, four adjacent first openings K1 enclose to form an imaginary quadrilateral, and the first via G1 is located at the center of the corresponding imaginary quadrilateral.

It can be understood that the center of the imaginary quadrilateral refers to the intersection point of the two diagonals of the imaginary quadrilateral. By locating the first via G1 at the center of the corresponding imaginary quadrilateral, more space is available for arrangement, and the first via G1 can be positioned as far away as possible from the four adjacent first openings K1 to avoid interference with the four adjacent first openings K1.

Depending on the arrangement pattern of the first openings K1, the imaginary quadrilateral may be a rectangle, rhombus, parallelogram, or another shape.

In one embodiment, a distance between the at least one first via G1 and an adjacent first opening K1 is greater than half of the first distance a1, to prevent interference between the first via G1 and the first opening K1. The distance between the first via G1 and the adjacent first opening K1 may be specifically the minimum distance between an edge of the first via G1 and the adjacent first opening K1.

In one embodiment, the imaginary quadrilateral is a rectangle.

In one embodiment, the imaginary quadrilateral is formed by connecting the centers or centroids of the four adjacent first openings K1, which is specifically selected according to the shape of the first openings K1.

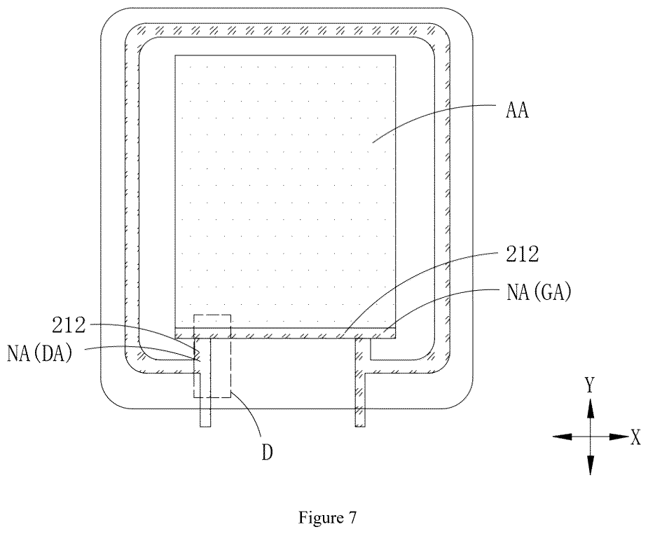

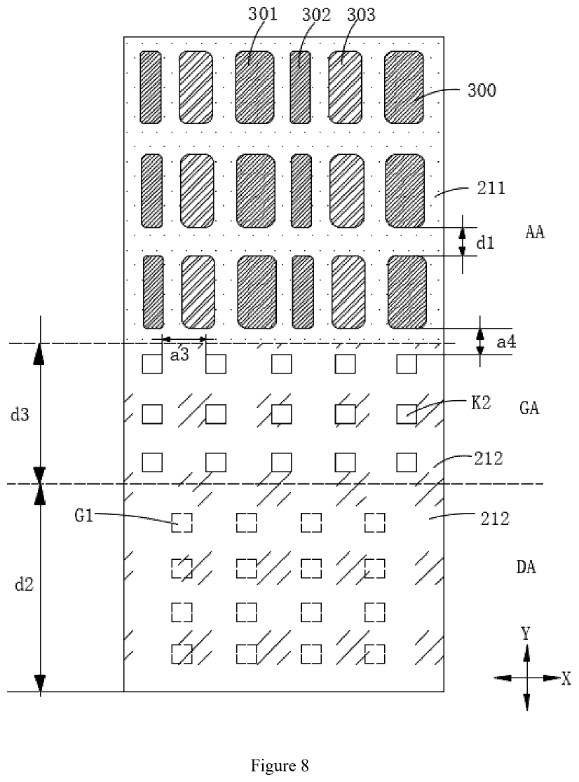

Referring to FIGS. 7 and 8, in some embodiments, the non-active area NA includes a first transition area GA1 and a lap area DA. In the first arrangement direction Y, at least part of the first transition area GA1 is located between the active area AA and the lap area DA, and the lap portion 212 further includes at least one second opening K2. The plurality of first openings K1 and the at least one first via G1 are provided in the lap area DA. The at least one second opening K2 is provided in the first transition area GA1 and extends from the side of the lap portion 212 facing away from the substrate 100 toward the substrate 100.

It should be noted that in this embodiment, both the lap area DA and the first transition area GA1 are provided with the lap portion 212, the lap portion 212 located in the lap area DA is provided with the plurality of first openings K1 and the at least one first via G1, and the lap portion 212 located in the first transition area GA1 is provided with the at least one second opening K2, thereby preventing the problem of film layer peeling in the lap portion 212. By providing the first transition area GA1, the current density concentrated in a relatively small area is alleviated. This allows the power voltage signal transmitted by the lap portion 212 to undergo initial dispersion in the first transition area GA1, reducing the current density before entering the active area AA, thereby mitigating the problem of thermal burn caused by a high current density.

In one embodiment, in the first arrangement direction Y, a minimum width d3 of the first transition area GA1 is greater than the first width d1, and a minimum width of the lap area DA is greater than the first width d1, to further mitigate the problem of a relatively high current density in the lap portion 212.

In one embodiment, in the first arrangement direction Y, the minimum width d3 of the first transition area GA1 is greater than the first width d1 and is less than the minimum width of the lap area DA, to ensure uniform current variation, avoid abrupt changes, and improve stability.

In one embodiment, in the first arrangement direction Y, the minimum width d3 of the first transition area GA1 is not less than 20 μm and not greater than 1000 μm, and the minimum width of the lap area DA is not less than 50 μm and not greater than 1000 μm.

For example, the minimum width d3 of the first transition area GA1 may be equal to any one of 20 μm, 50 μm, 200 μm, 400 μm, 600 μm, 800 μm, or 1000 μm.

Referring to FIG. 8, in some embodiments, the at least one second opening K2 includes a plurality of second openings K2, and two adjacent second openings K2 have a third distance a3 defined therebetween, the third distance a3 being greater than the first width d1.

When the second openings K2 are provided, the third distance a3 between adjacent second openings K2 is the width of the lap portion 212 between the adjacent second openings K2, and this width affects the current density in the lap portion 212 between the adjacent second openings K2. Therefore, in this embodiment, the second distance a2 is set to be greater than the first width d1 to decrease the impedance of the lap portion 212 between the adjacent second openings K2 and decrease the current density in the lap portion 212, thereby mitigating the problem of thermal burn caused by a high current density.

In one embodiment, the first distance a1 is greater than the third distance a3 to ensure uniform current variation, avoid abrupt changes, and improve stability.

In one embodiment, the distance between the two adjacent second openings K2 may be specifically the distance along the direction of the connecting line between the centers of the two second openings K2. For example, along the first direction, the two adjacent second openings K2 have the third distance a3 defined therebetween; and/or along the second direction, the two adjacent second openings K2 have the third distance a3 defined therebetween, where the first direction and the second direction are both parallel to the substrate 100, and the first direction intersects with the second direction.

In some embodiments, the first opening K1 penetrates through the lap portion 212; that is, the first opening K1 may be a through hole, and portions of the lap portion 212 are separated by the first opening K1. When the first opening K1 penetrates through the lap portion 212, the heat dissipation effect is better.

In some embodiments, a distance the first opening K1 extends from the side of the lap portion 212 facing away from the substrate 100 toward the substrate 100 is less than a thickness of the lap portion 212 in a direction perpendicular to the substrate 100. That is, the first opening K1 does not penetrate through the lap portion 212, but only with the material of the lap portion 212 on one side surface of the lap portion 212 facing away from the substrate 100 being partially removed to form the first opening K1. This ensures that the lap portion 212 is not completely disconnected, which equivalently increases the width of the lap portion 212 and thus mitigates burn.

In some embodiments, the isolation structure 210 includes a first sub-layer 201 and a second sub-layer 202 sequentially stacked along a direction away from the substrate 100, where an orthographic projection of the first sub-layer 201 on the substrate 100 is within an orthographic projection of the second sub-layer 202 on the substrate 100.

The second opening K2 penetrates through the second sub-layer 202 and the first sub-layer 201.

It can be understood that the second opening K2 may penetrate through the first sub-layer 201 and the second sub-layer 202 to expose a film layer below the lap portion 212, where the film layer below may be specifically an insulation layer 140. The orthographic projection of the first sub-layer 201 on the substrate 100 being within the orthographic projection of the second sub-layer 202 on the substrate 100 means that the size of the first sub-layer 201 is less than or equal to the size of the second sub-layer 202.

In one embodiment, the first sub-layer 201 includes an aluminum metal material, and the second sub-layer 202 includes a titanium metal material.

In one embodiment, the lap portion 212 further includes a fifth sub-layer located on one side of the first sub-layer 201 facing the substrate 100, where the orthographic projection of the first sub-layer 201 on the substrate 100 is within an orthographic projection of the fifth sub-layer on the substrate 100. The second opening K2 may also penetrate through the fifth sub-layer.

In some embodiments, the second opening K2 penetrates through the second sub-layer 202 and extends into the first sub-layer 201, where a distance the second opening K2 extends into the first sub-layer 201 is less than a thickness of the first sub-layer 201 in the direction perpendicular to the substrate 100.

In this embodiment, the second opening K2 penetrates through the second sub-layer 202 but does not penetrate through the first sub-layer 201, which can be achieved by a half-etching process. This ensures that the first sub-layer 201 remains connected and is not interrupted by the second opening K2. This configuration equivalently increases the trace width of the lap portion 212 and thus mitigates burn.

In one embodiment, the second opening K2 includes a first sub-opening K11 and a second sub-opening K12 communicated with the first sub-opening K11, where the first sub-opening K11 is provided in the first sub-layer 201, and the second sub-opening K12 is provided in the second sub-layer 202. An orthographic projection of the second sub-opening K12 on the substrate 100 is within an orthographic projection of the first sub-opening K11 on the substrate 100; that is, the size of the second sub-opening K12 is less than or equal to the size of the first sub-opening K11. When the size of the second sub-openings K12 is less than the size of the first sub-opening K11, the second sub-layer 202 protrudes toward the center of the second sub-opening K12 relative to the first sub-layer 201. A deposited film layer, such as an inorganic encapsulation layer, on the lap portion 212 may partially recess into the first sub-opening K11 and the second sub-opening K12 to increase the adhesion between the inorganic encapsulation layer and the lap portion 212, thereby preventing film layer peeling.

Referring to FIG. 8, in some embodiments, the plurality of isolation openings 220 and the at least one second opening K2 have a fourth distance a4 defined therebetween, the fourth distance a4 being greater than the first width d1.

It can be understood that, since at least part of the first transition area GA1 is located between the active area AA and the lap area DA, the second opening K2 is closer to the isolation opening 220 compared with the second opening K2 provided in the lap area DA. The width of the lap portion 212 between the isolation opening 220 and the second opening K2 should not be too small, as a too small width would cause an excessive current density in this portion of the lap portion 212. Therefore, in this embodiment, the plurality of isolation openings 220 and the plurality of second openings K2 are configured to have the fourth distance a4 defined therebetween, and the fourth distance a4 is greater than the first width d1. The fourth distance a4 is one of the corresponding plurality of distances between the plurality of isolation openings 220 and the plurality of second openings K2. This ensures that even the lap portion 212 having the minimum width between the isolation opening 220 and the second opening K2 will not experience overheating due to an excessive current density.

In one embodiment, the fourth distance a4 is not less than 8 μm and not greater than 50 μm.

For example, the fourth distance a4 may be equal to any one of 8 μm, 20 μm, 30 μm, 40 μm, or 50 μm.

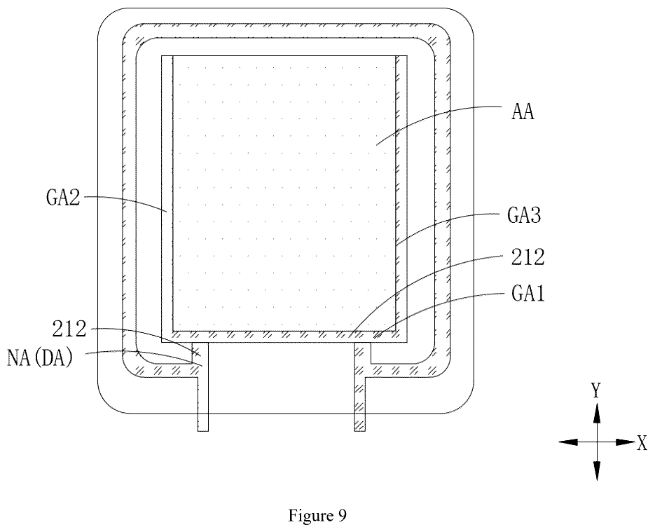

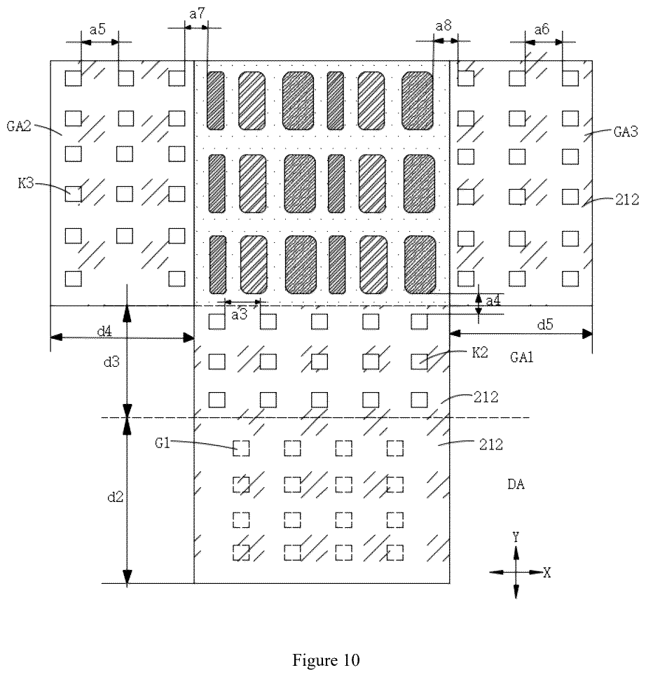

Referring to FIGS. 9 and 10, in some embodiments, the non-active area NA further includes a second transition area GA2, the second transition area GA2 and the active area AA are arranged in the second arrangement direction X, and the first arrangement direction Y intersects with the second arrangement direction X. The lap portion 212 further includes at least one third opening K3 provided in the second transition area GA2 and extending from the side of the lap portion 212 facing away from the substrate 100 toward the substrate 100.

In addition to the first transition area GA1, the second transition area GA2 may also be provided on one side of the active area AA in the second arrangement direction X. The second transition area GA2 is provided with the lap portion 212, and the lap portion 212 is provided with the at least one third opening K3 in the second transition area GA2. The third opening K3 extending from the side of the lap portion 212 facing away from the substrate 100 toward the substrate 100 means that the third opening K3 may completely penetrate through the lap portion 212, or may not penetrate through the lap portion 212; that is, the third opening K3 may be configured as a blind hole.

In one embodiment, in the second arrangement direction X, a minimum width d4 of the second transition area GA2 is greater than the first width d1 to decrease the impedance of the lap portion 212 in the second transition area GA2 and decrease the current density in the lap portion 212, thereby mitigating the problem of thermal burn caused by a high current density. Furthermore, this allows the power voltage signal transmitted by the lap portion 212 to undergo initial dispersion in the second transition area GA2, reducing the current density before entering the active area AA, thereby mitigating the problem of thermal burn caused by a high current density.

In one embodiment, in the second arrangement direction X, the minimum width d4 of the second transition area GA2 is not less than 20 μm and not greater than 1000 μm.

For example, the minimum width d4 of the second transition area GA2 may be equal to any one of 20 μm, 50 μm, 200 μm, 400 μm, 600 μm, 800 μm, or 1000 μm.

Referring to FIGS. 9 and 10, optionally, the non-active area NA further includes a third transition area GA3. In the second arrangement direction X, the active area AA is located between the second transition area GA2 and the third transition area GA3, where the lap portion 212 further includes at least one fourth opening K4 provided in the third transition area GA3 and extending from the side of the lap portion 212 facing away from the substrate 100 toward the substrate 100.

The third transition area GA3 is provided with the lap portion 212, and the lap portion 212 is provided with at least one third opening K3 in the third transition area GA3. The fourth opening K4 extending from the side of the lap portion 212 facing away from the substrate 100 toward the substrate 100 means that the fourth opening K4 may completely penetrate through the lap portion 212, or may not penetrate through the lap portion 212; that is, the fourth opening K4 may be configured as a blind hole.

In one embodiment, in the second arrangement direction X, a minimum width d5 of the third transition area GA3 is greater than the first width d1 to decrease the impedance of the lap portion 212 in the third transition area GA3 and decrease the current density in the lap portion 212, thereby mitigating the problem of thermal burn caused by a high current density. Furthermore, this allows the power voltage signal transmitted by the lap portion 212 to undergo initial dispersion in the third transition area GA3, reducing the current density before entering the active area AA, thereby mitigating the problem of thermal burn caused by a high current density.

In one embodiment, in the second arrangement direction X, the minimum width d5 of the third transition area GA3 is not less than 20 μm and not greater than 1000 μm.

For example, in the second arrangement direction X, the minimum width d5 of the third transition area GA3 may be equal to any one of 20 μm, 50 μm, 200 μm, 400 μm, 600 μm, 800 μm, or 1000 μm.

Referring to FIG. 10, in some embodiments, the at least one third opening K3 includes a plurality of third openings K3, and two adjacent third openings K3 have a fifth distance a5 defined therebetween, the fifth distance a5 being greater than the first width d1.

When the third openings K3 are provided, the third distance a3 between adjacent third openings K3 is the width of the lap portion 212 between the adjacent third openings K3, and this width affects the current density in the lap portion 212 between the adjacent third openings K3. Therefore, in this embodiment, the fifth distance a5 is set to be greater than the first width d1 to decrease the impedance of the lap portion 212 between the adjacent third openings K3 and decrease the current density in the lap portion 212, thereby mitigating the problem of thermal burn caused by a high current density.

In one embodiment, the at least one fourth opening K4 includes a plurality of fourth openings K4, and two adjacent fourth openings K4 have a sixth distance a6 defined therebetween, the sixth distance a6 being greater than the first width d1.

Similarly, the third distance a3 between adjacent fourth openings K4 is the width of the lap portion 212 between the adjacent fourth openings K4, and this width affects the current density in the lap portion 212 between the adjacent fourth openings K4. Therefore, in this embodiment, the sixth distance a6 is set to be greater than the first width d1 to decrease the impedance of the lap portion 212 between the adjacent fourth openings K4 and decrease the current density in the lap portion 212, thereby mitigating the problem of thermal burn caused by a high current density.

In one embodiment, the distance between the two adjacent third openings K3 may be specifically the distance along the direction of the connecting line between the centers of the two third openings K3. For example, along the first direction, the two adjacent third openings K3 have the fifth distance a5 defined therebetween; and/or along the second direction, the two adjacent third openings K3 have the fifth distance a5 defined therebetween, where the first direction and the second direction are both parallel to the substrate 100, and the first direction intersects with the second direction.

In one embodiment, the distance between the two adjacent fourth openings K4 may be specifically the distance along the direction of the connecting line between the centers of the two fourth openings K4. For example, along the first direction, the two adjacent fourth openings K4 have the sixth distance a6 defined therebetween; and/or along the second direction, the two adjacent fourth openings K4 have the sixth distance a6 defined therebetween, where the first direction and the second direction are both parallel to the substrate 100, and the first direction intersects with the second direction.

Referring to FIG. 10, in some embodiments, the plurality of isolation openings 220 and the at least one third opening K3 have a seventh distance a7 defined therebetween, the seventh distance a7 being greater than the first width d1. The seventh distance a7 is not less than 8 μm and not greater than 50 μm. This ensures that even the lap portion 212 having the minimum width between the isolation opening 220 and the third opening K3 will not experience overheating due to an excessive current density. For example, the seventh distance a7 may be equal to any one of 8 μm, 20 μm, 30 μm, 40 μm, or 50 μm.

In one embodiment, along the second arrangement direction X, the plurality of isolation openings 220 and the at least one third opening K3 have the seventh distance a7 defined therebetween.

In one embodiment, the plurality of isolation openings 220 and the at least one fourth opening K4 have an eighth distance a8 defined therebetween, the eighth distance a8 being greater than the first width d1. The eighth distance a8 is not less than 8 μm and not greater than 50 μm. This ensures that even the lap portion 212 having the minimum width between the isolation opening 220 and the fourth opening K4 will not experience overheating due to an excessive current density. For example, the eighth distance a8 may be equal to any one of 8 μm, 20 μm, 30 μm, 40 μm, or 50 μm.

In one embodiment, along the second arrangement direction X, the plurality of isolation openings 220 and the at least one fourth opening K4 have the eighth distance a8 defined therebetween.

In some embodiments, a length of the second transition area GA2 in the first arrangement direction Y is greater than a length of the first transition area GA1 in the second arrangement direction X, thereby allowing the power voltage signal to disperse in the second transition area GA2 along the first arrangement direction Y and preventing excessive current concentration.

In one embodiment, a length of the third transition area GA3 in the first arrangement direction Y is greater than the length of the first transition area GA1 in the second arrangement direction X; that is, the power voltage signal can disperse in the third transition area GA3 along the first arrangement direction Y, preventing excessive current concentration.

In some embodiments, the display panel further includes: a first encapsulation layer 410 including a plurality of first encapsulation portions, each first encapsulation portion covering one side of each corresponding light-emitting device 300 facing away from the substrate 100. The first encapsulation portion provides sealing protection for the light-emitting device 300.

In one embodiment, the first encapsulation layer 410 is further located in the non-active area NA, and the first encapsulation layer 410 located in the non-active area NA is provided on one side of the lap portion 212 facing away from the substrate 100, to provide encapsulation protection for the lap portion 212.

In one embodiment, the display panel further includes a second encapsulation layer 420 provided on one side of the first encapsulation layer 410 facing away from the substrate 100. A material of the second encapsulation layer 420 includes an organic material. The second encapsulation layer 420 may have an appropriate thickness to ensure a flatter surface on one side of the second encapsulation layer 420 facing away from the substrate 100, thereby improving the flatness of the display panel.

In one embodiment, the display panel further includes a third encapsulation layer 430 provided on one side of the second encapsulation layer 420 facing away from the substrate 100.

The third encapsulation layer 430 extends from the active area AA to the non-active area NA to provide complete protection for the film layer structure on one side of the third encapsulation layer facing the substrate 100.

In one embodiment, a material of the third encapsulation layer 430 includes an inorganic material, which imparts good compactness to the third encapsulation layer 430, thereby improving the encapsulation performance of the display panel.

In one embodiment, the first encapsulation layer 410 and the third encapsulation layer 430 are made of the same material to reduce production costs.

An embodiment of the present application further provides a display apparatus, including the display panel according to any one of the above-described embodiments. Since the display apparatus according to this embodiment includes the display panel according to any one of the above-described embodiments, the display apparatus according to this embodiment has the beneficial effects as the display panel according to any one of the above-described embodiments, which will not be repeated herein.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

Although the present application is described with reference to some embodiments, various modifications can be made, and equivalents can be provided to substitute for the components thereof without departing from the scope of the present application. In particular, the features mentioned in the embodiments can be combined in any manner, provided that there is no structural conflict. The present application is not limited to the specific embodiments disclosed herein but includes all the embodiments that fall within the scope of the claims.

What is claimed is:

1. A display panel, having an active area and a non-active area, the display panel comprising:
a substrate;
an isolation structure provided on one side of the substrate and comprising an isolation portion and a lap portion, wherein the isolation portion encloses to form a plurality of isolation openings located in the active area, and the lap portion is located in the non-active area; and
a plurality of light-emitting devices, at least part of each light-emitting device being located in each corresponding isolation opening,
wherein a width of the isolation portion between two adjacent light-emitting devices is a first width, and along a first arrangement direction of the isolation portion and the lap portion, a minimum width of the lap portion is a second width, the second width being greater than the first width.

2. The display panel according to claim 1, wherein the lap portion comprises a plurality of first openings, each first opening extending from one side of the lap portion facing away from the substrate toward the substrate, wherein
two adjacent first openings have a first distance defined therebetween, the first distance being greater than the first width;
the first distance is not less than 1.5 times the first width;
the first width is not less than 3 μm and not greater than 20 μm;
the second width is not less than 50 μm and not greater than 1000 μm;
the first distance is not less than 10 μm and not greater than 70 μm;
along a first direction, a width of the isolation portion between two adjacent light-emitting devices is the first width, or along a second direction, a width of the isolation portion between two adjacent light-emitting devices is the first width, wherein the first direction and the second direction are both parallel to the substrate, and the first direction intersects with the second direction;
along the first direction, a minimum width of the lap portion is the second width, or along the second direction, a minimum width of the lap portion is the second width; and
along the first direction, two adjacent first openings have the first distance defined therebetween, or along the second direction, two adjacent first openings have the first distance defined therebetween.

3. The display panel according to claim 2, wherein an area of a shape enclosed by an orthographic projection of the contour of the first opening on the substrate is less than an area of an orthographic projection of the isolation opening on the substrate.

4. The display panel according to claim 2, wherein the first opening penetrates through the lap portion, or a distance the first opening extends from the side of the lap portion facing away from the substrate toward the substrate is less than a thickness of the lap portion in a direction perpendicular to the substrate.

5. The display panel according to claim 4, wherein the isolation structure comprises a first sub-layer and a second sub-layer sequentially stacked along a direction away from the substrate, wherein an orthographic projection of the first sub-layer on the substrate is within an orthographic projection of the second sub-layer on the substrate;
the first opening penetrates through the second sub-layer and the first sub-layer, or
the first opening penetrates through the second sub-layer and extends into the first sub-layer, wherein a distance the first opening extends into the first sub-layer is less than a thickness of the first sub-layer in the direction perpendicular to the substrate; and
the first opening comprises a first sub-opening and a second sub-opening communicated with the first sub-opening, wherein the first sub-opening is provided in the first sub-layer, the second sub-opening is provided in the second sub-layer, and a shape enclosed by an orthographic projection of the contours of the second sub-opening on the substrate is within a shape enclosed by an orthographic projection of the contours of the first sub-opening on the substrate.

6. The display panel according to claim 2, wherein the plurality of isolation openings and the plurality of first openings have a second distance defined therebetween, the second distance being greater than the first width;
the second distance is not less than 8 μm and not greater than 50 μm; and
the isolation portion and the lap portion are of an integral structure.

7. The display panel according to claim 1, wherein the isolation portion comprises a first isolation portion extending in a first direction parallel to the substrate, a second isolation portion extending in a second direction parallel to the substrate, and a third isolation portion connected to both the first isolation portion and the second isolation portion, the first direction intersecting with the second direction, wherein
a maximum width of at least one third isolation portion is greater than a maximum width of the first isolation portion connected to the third isolation portion, and the maximum width of the at least one third isolation portion is greater than a maximum width of the second isolation portion connected to the third isolation portion; and
the first width is the maximum width of the third isolation portion, or the first width is the maximum width of the third isolation portion in the first direction, or the first width is the maximum width of the third isolation portion in the second direction.

8. The display panel according to claim 2, further comprising:
a pixel defining layer provided on one side of the substrate and located in the active area and the non-active area, wherein the pixel defining layer encloses to form a plurality of pixel openings located in the active area, and each pixel opening is in communication with each corresponding isolation opening,
wherein orthographic projections of the plurality of first openings on the substrate are within an orthographic projection of the pixel defining layer on the substrate;
the isolation structure is located on one side of the pixel defining layer facing away from the substrate;
the pixel defining layer further comprises at least one first via located in the non-active area, and the display panel further comprises:
a driving layer, provided between the substrate and the pixel defining layer and located in the active area and the non-active area, comprising at least one power signal line located in the non-active area, wherein part of a surface on a side of the at least one power signal line facing away from the substrate is exposed from the at least one first via, wherein the lap portion is electrically connected to the at least one power signal line through the at least one first via;
the driving layer further comprises an insulation layer provided between the at least one power signal line and the pixel defining layer, wherein the insulation layer comprises at least one second via, and an orthographic projection of the at least one first via on the substrate is within an orthographic projection of the at least one second via on the substrate;
the at least one first via comprises a plurality of first vias, the at least one second via comprises a plurality of second vias, and the plurality of first vias and the plurality of second vias are provided in a one-to-one correspondence;
the insulation layer comprises an organic material, and the pixel defining layer comprises an inorganic material; and
the pixel defining layer covers a side surface of the insulation layer facing the at least one second via.

9. The display panel according to claim 8, wherein the plurality of first openings are arranged in an array in the first direction and the second direction, wherein four adjacent first openings enclose to form an imaginary quadrilateral, and the first via is located at the center of the corresponding imaginary quadrilateral;
a distance between the at least one first via and an adjacent first opening is greater than half of the first distance;
the imaginary quadrilateral is a rectangle; and
the imaginary quadrilateral is formed by connecting the centers or centroids of the four adjacent first openings.

10. The display panel according to claim 8, wherein the non-active area comprises a first transition area and a lap area; in the first arrangement direction, at least part of the first transition area is located between the active area and the lap area, and the lap portion further comprises at least one second opening, wherein
the plurality of first openings and the at least one first via are provided in the lap area;
the at least one second opening is provided in the first transition area and extends from the side of the lap portion facing away from the substrate toward the substrate;
in the first arrangement direction, a minimum width of the first transition area is greater than the first width, and a minimum width of the lap area is greater than the first width; and
in the first arrangement direction, the minimum width of the first transition area is not less than 20 μm and not greater than 1000 μm, and the minimum width of the lap area is not less than 50 μm and not greater than 1000 μm.

11. The display panel according to claim 10, wherein the at least one second opening comprises a plurality of second openings, and two adjacent second openings have a third distance defined therebetween, the third distance being greater than the first width;
each second opening penetrates through the lap portion, or a distance the second opening extends from the side of the lap portion facing away from the substrate toward the substrate is less than a thickness of the lap portion in a direction perpendicular to the substrate;
the isolation structure comprises a first sub-layer and a second sub-layer sequentially stacked along a direction away from the substrate, wherein an orthographic projection of the first sub-layer on the substrate is within an orthographic projection of the second sub-layer on the substrate, wherein
the second opening penetrates through the second sub-layer and the first sub-layer; or
the second opening penetrates through the second sub-layer and extends into the first sub-layer, wherein a distance the second opening extends into the first sub-layer is less than a thickness of the first sub-layer in the direction perpendicular to the substrate;
the second opening comprises a third sub-opening and a fourth sub-opening communicated with the third sub-opening, wherein the third sub-opening is provided in the first sub-layer, the fourth sub-opening is provided in the second sub-layer, and an orthographic projection of the fourth sub-opening on the substrate is within an orthographic projection of the third sub-opening on the substrate; and
along the first direction, two adjacent second openings have the third distance defined therebetween, or along the second direction, two adjacent second openings have the third distance defined therebetween.

12. The display panel according to claim 11, wherein the first distance is greater than the third distance.

13. The display panel according to claim 10, wherein the plurality of isolation openings and the at least one second opening have a fourth distance defined therebetween, the fourth distance being greater than the first width; and
the fourth distance is not less than 8 μm and not greater than 50 μm.

14. The display panel according to claim 10, wherein the non-active area further comprises a second transition area, the second transition area and the active area are arranged in a second arrangement direction, and the first arrangement direction intersects with the second arrangement direction, wherein
the lap portion further comprises at least one third opening provided in the second transition area and extending from the side of the lap portion facing away from the substrate toward the substrate;
in the second arrangement direction, a minimum width of the second transition area is greater than the first width; and
in the second arrangement direction, the minimum width of the second transition area is not less than 20 μm and not greater than 1000 μm;
the non-active area further comprises a third transition area, and in the second arrangement direction, the active area is located between the second transition area and the third transition area, wherein the lap portion further comprises at least one fourth opening provided in the third transition area and extending from the side of the lap portion facing away from the substrate toward the substrate;
in the second arrangement direction, a minimum width of the third transition area is greater than the first width; and
in the second arrangement direction, the minimum width of the third transition area is not less than 20 μm and not greater than 1000 μm.

15. The display panel according to claim 14, wherein
the at least one third opening comprises a plurality of third openings, and two adjacent third openings have a fifth distance defined therebetween, the fifth distance being greater than the first width;
the at least one fourth opening comprises a plurality of fourth openings, and two adjacent fourth openings have a sixth distance defined therebetween, the sixth distance being greater than the first width;
along the first direction, the two adjacent third openings have the fifth distance defined therebetween; or along the second direction, the two adjacent third openings have the fifth distance defined therebetween; and
along the first direction, the two adjacent fourth openings have the sixth distance defined therebetween; or along the second direction, the two adjacent fourth openings have the sixth distance defined therebetween.

16. The display panel according to claim 14, wherein
the plurality of isolation openings and the at least one third opening have a seventh distance defined therebetween, the seventh distance being greater than the first width, and the seventh distance being not less than 8 μm and not greater than 50 μm; and
the plurality of isolation openings and the at least one fourth opening have an eighth distance defined therebetween, the eighth distance being greater than the first width, and the eighth distance being no less than 8 μm and no greater than 50 μm.

17. The display panel according to claim 14, wherein
a length of the second transition area in the first arrangement direction is greater than a length of the first transition area in the second arrangement direction; and
a length of the third transition area in the first arrangement direction is greater than the length of the first transition area in the second arrangement direction.

18. The display panel according to claim 1, wherein the isolation structure comprises a conductive material, and the light-emitting device comprises a first electrode, a light-emitting structure, and a second electrode sequentially stacked in a direction away from the substrate, wherein the second electrode is electrically connected to the isolation portion.

19. The display panel according to claim 1, further comprising:
a first encapsulation layer comprising a plurality of first encapsulation portions, each first encapsulation portion covering one side of each corresponding light-emitting device facing away from the substrate;
the first encapsulation layer is further located in the non-active area, and the first encapsulation layer located in the non-active area is provided on one side of the lap portion facing away from the substrate;
the display panel further comprises a second encapsulation layer provided on one side of the first encapsulation layer facing away from the substrate;
the display panel further comprises a third encapsulation layer provided on one side of the second encapsulation layer facing away from the substrate;
the first encapsulation layer and the third encapsulation layer are made of the same material; and
the first encapsulation layer and the third encapsulation layer comprise an inorganic material, and the second encapsulation layer comprise an organic material.

20. A display apparatus, comprising:
a display panel, having an active area and a non-active area, the display panel comprising:
a substrate;
an isolation structure provided on one side of the substrate and comprising an isolation portion and a lap portion, wherein the isolation portion encloses to form a plurality of isolation openings located in the active area, and the lap portion is located in the non-active area; and
a plurality of light-emitting devices, at least part of each light-emitting device being located in each corresponding isolation opening,
wherein a width of the isolation portion between two adjacent light-emitting devices is a first width, and along a first arrangement direction of the isolation portion and the lap portion, a minimum width of the lap portion is a second width, the second width being greater than the first width.
